(19) United States
(12) Patent Application Publication
(10) Pub. No.: US 2018/0209748 A1
(43) Pub. Date: Jul. 26, 2018

(54) THERMOELECTRIC MODULE WITH FASTENING ELEMENT THERMAL ISOLATION FEATURE FOR VEHICLE BATTERY

(71) Applicant: Gentherm Inc., Northville, MI (US)

(72) Inventors: David Scott Thomas, Royal Oak, MI (US); Martin Adldinger, Holzheim (DE); Rüdiger Spillner, Augsburg (DE); Benjamin Schraff, Augsburg (DE); Horst Georg Johannes Sieber, Aldorf (DE)

(21) Appl. No.: 15/580,497

(22) PCT Filed: Jun. 8, 2016
(86) PCT No.: PCT/US2016/036406

§ 371 Date: Dec. 7, 2017

Related U.S. Application Data
(60) Provisional application No. 62/173,472, filed on Jun. 10, 2015.

(51) Int. Cl. F28D 15/06; F16B 5/02; F16B 5/06; F16B 29/00; F16B 43/00; F25B 21/02; F28F 13/00; H01L 35/32; H01M 10/6572

(52) U.S. Cl. CPC F28D 15/06; F16B 5/0258; F16B 5/065; F16B 29/00; F16B 43/001; F28D 2021/0029; F28F 13/00; H01L 35/32; H01M 10/6572; F25B 2321/023; F25B 21/02

(57) ABSTRACT

A thermoelectric module assembly for thermally conditioning a component includes first and second members that are spaced apart from one another and are configured to respectively provide cold and hot sides. An insulator plate is arranged between the first and second members. A thermoelectric device is arranged within the insulator plate and is operatively engaged with the first and second members. A fastening element secures the first and second members to one another about the insulator plate in an assembled condition. A thermal insulator is provided in one of the first and the second members and is configured to receive the fastening element.

### CROSS-REFERENCE TO RELATED APPLICATIONS

This application claims priority to U.S. Provisional Application No. 62/173,472, which was filed on Jun. 10, 2015 and is incorporated herein by reference.

### BACKGROUND

This disclosure relates to a thermoelectric module used to cool a vehicle component, such as a battery. In particular, the disclosure relates to thermal isolation features within the thermoelectric module to improve heat transfer efficiency.

Lithium ion batteries are used in passenger and other types of vehicles to provide power to electric motors that provide propulsion to the vehicle. Such batteries can generate a significant amount of heat such that the battery must be cooled to prevent performance degradation.

One type of vehicle battery cooling arrangement that has been proposed that includes a thermoelectric module arranged beneath the battery and adjacent to a cold plate assembly. The thermoelectric module includes thermoelectric devices that operate based upon the Peltier effect to provide cooling adjacent to the battery. Heat transferred through the thermoelectric device is rejected to the cold plate assembly, which may have a cooling fluid circulated therethrough and sent to a heat exchanger.

It is desirable to design the thermoelectric module so as to efficiently transfer heat through some components within the thermoelectric module while insulating other components within the thermoelectric module.

### SUMMARY

In one exemplary embodiment, a thermoelectric module assembly for thermally conditioning a component includes first and second members that are spaced apart from one another and are configured to respectively provide cold and hot sides. An insulator plate is arranged between the first and second members. A thermoelectric device is arranged within the insulator plate and is operatively engaged with the first and second members. A fastening element secures the first and second members to one another about the insulator plate in an assembled condition. A thermal insulator is provided in one of the first and the second members and is configured to receive the fastening element.

In a further embodiment of the above, the first and second members are metallic and the insulator plate is a plastic.

In a further embodiment of any of the above, the fastening element is metallic and the thermal insulator is non-metallic.

In a further embodiment of any of the above, the second heat member includes a raised pad that supports the thermoelectric device.

In a further embodiment of any of the above, a thermal foil is arranged between and in engagement with the pad and the thermoelectric device.

In a further embodiment of any of the above, the thermoelectric device is a Peltier device.

In a further embodiment of any of the above, the insulator plate includes an opening and the second member includes a protrusion that cooperates with the opening to laterally locate the insulator plate and the second member relative to one another.

In a further embodiment of any of the above, the fastening element is a threaded fastener secured to a threaded inner diameter of the protrusion.

In a further embodiment of any of the above, the insulator plate has at least four discrete protrusions that surround the thermoelectric device.

In a further embodiment of any of the above, the first and second members are first and second heat spreaders. The first and second heat spreaders and the insulator plate are secured to one another to provide the thermoelectric module assembly.

In a further embodiment of any of the above, the first member provides a heat spreader and the second member provides a cold plate assembly. The cold plate assembly includes cooling passages configured to receive a coolant circulated through the cooling passages.

In a further embodiment of any of the above, the thermal insulator is press-fit into the second member.

In a further embodiment of any of the above, the thermal insulator is threaded into the second member.

In a further embodiment of any of the above, the fastening element is threaded into the thermal insulator.

In a further embodiment of any of the above, the fastening element is press-fit into the thermal insulator.

In a further embodiment of any of the above, an interface between the fastening element and the thermal insulator provides a clamping load on the thermoelectric device.

In a further embodiment of any of the above, the fastening element is thermally isolated from the second member by the thermal isolator.

In a further embodiment of any of the above, the thermal insulator is a washer that engages the first member.

In a further embodiment of any of the above, the thermal insulator is integrated with the insulator plate.

In another exemplary embodiment, an insulating assembly includes an insulator plate that includes a neck with an end. A component with a hole is aligned with the end. A fastener is received in the hole and is secured to the neck. The fastener is configured to plastically deform the end into engagement with the component during assembly and isolate the component from the fastener.

### BRIEF DESCRIPTION OF THE DRAWINGS

The disclosure can be further understood by reference to the following detailed description when considered in connection with the accompanying drawings wherein:

FIG. 1A is a highly schematic view of a vehicle with a vehicle system temperature regulated by a cooling system.

FIG. 1B illustrates a cooling system that includes a thermoelectric module assembly and a cold plate assembly.

FIG. 2 is an exploded perspective view of a thermoelectric module assembly.

FIG. 3A is a perspective view of the insulator plate mounted to a heat spreader.

FIG. 3B is a perspective view of the insulator plate and heat spreader shown in FIG. 3A with thermoelectric devices arranged within the insulator plate.

FIG. 4 is a perspective view of the thermoelectric module assembly.

FIG. 5 is a cross-sectional view of one thermoelectric module assembly.

FIG. 6 is a cross-sectional view of another thermoelectric module assembly.

FIG. 7 illustrates a schematic cross-sectional view of another insulator arrangement.

FIGS. 8-8D illustrates another schematic cross-sectional view of yet another insulator arrangement.

FIGS. 9A-9Z depict various example insulator designs.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### DETAILED DESCRIPTION

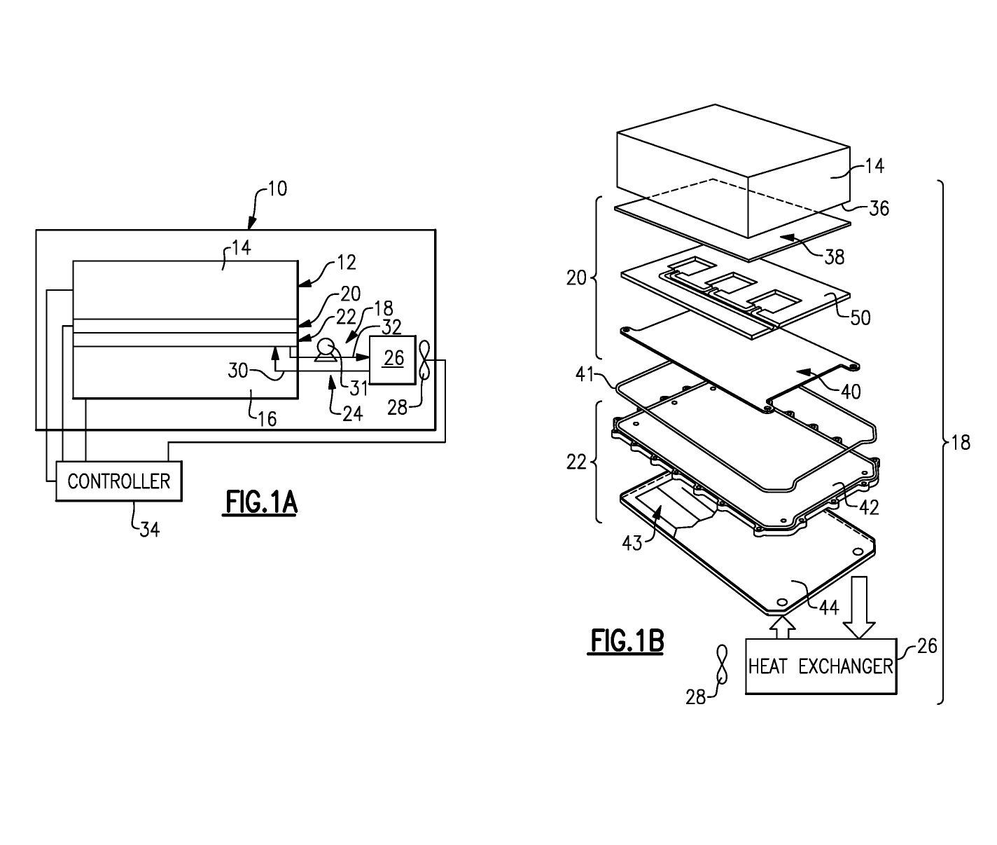

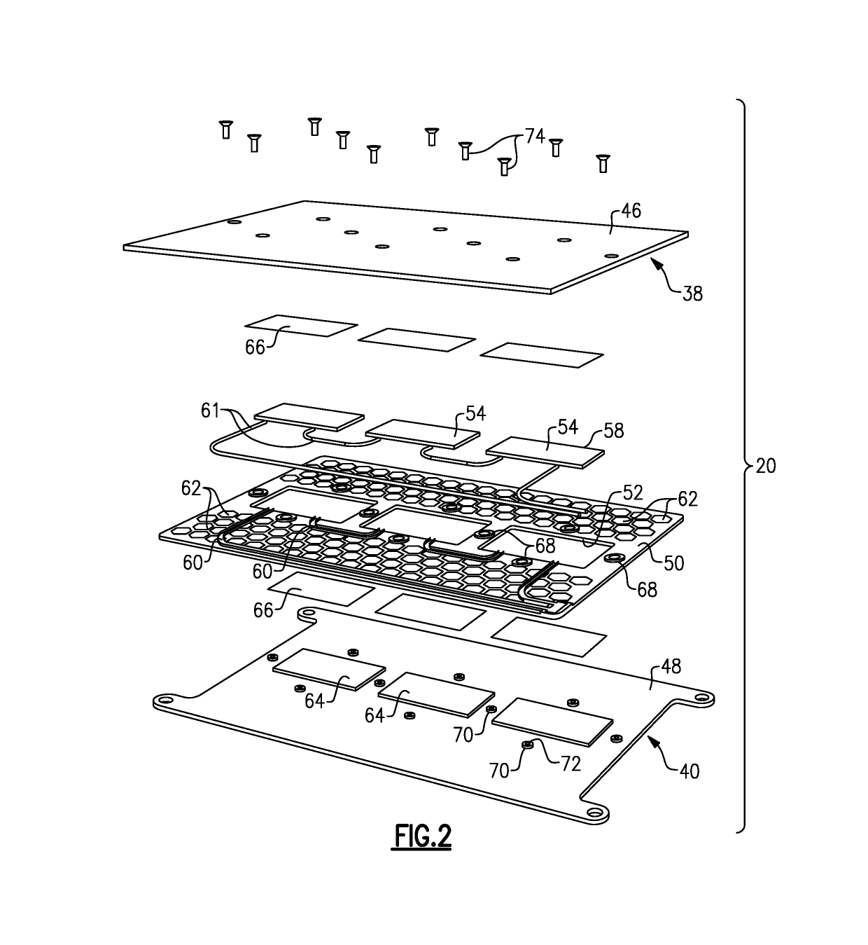

A vehicle 10 is schematically illustrated in FIG. 1A. The vehicle 10 includes a vehicle system 12 that either needs to be heated or cooled. In one example, the vehicle system 12 includes a battery 14, such as a lithium ion battery used for vehicle propulsion that generates a significant amount of heat. Such a battery must be cooled during operation otherwise the battery efficiency and/or integrity may degrade.

A cooling system 18 is arranged between the battery 14 and a DC/DC converter 16 in a stack to remove heat from the battery 14 thus cooling the vehicle system 12. The DC/DC converter 16 provides an electrical interface between the battery 14 and the vehicle electrics. A cooling system 18 includes a thermoelectric module assembly 20 mounted to a cold plate assembly 22 that is in communication with a cooling loop 24. A cooling fluid, such as glycol, is circulated by a pump 31 within the cooling loop 24. Heat is rejected to the coolant via the cold plate assembly 22 through supply and return coolant lines 30, 32 that are connected to a heat exchanger 26. A fan or blower 28 may be used to remove heat from the coolant within the heat exchanger 26 to an ambient environment, for example.

A controller 34 communicates with various components of the vehicle 10, vehicle system 12 and cooling system 18 to coordinate battery cooling. Sensors and outputs (not shown) may be connected to the controller 34.

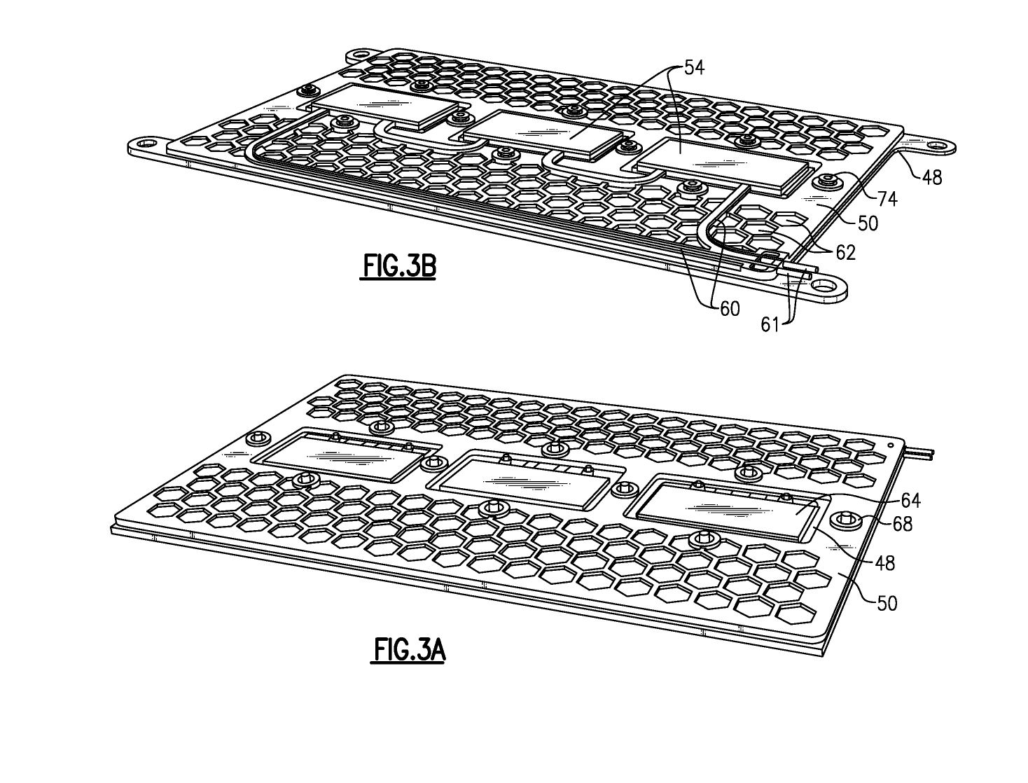

An example cooling system 18 is shown in more detail in FIG. 1B. The thermoelectric module assembly 20 includes a cold side 38 that supports a surface 36 of the battery 14. An insulator plate 50 carries thermoelectric devices (shown at 58 in FIG. 2) and separates the cold side 38 (at the battery 14) from a hot side 40 (at the cold plate assembly 22).

The cold plate assembly 22 includes first and second cold plates 42, 44 secured to one another to enclose a network of fluid passages (shown schematically at 43) that communicate coolant across the cold plate assembly 22 to receive heat rejected from the hot side 40. A seal 41 may be provided between the thermoelectric module assembly 20 and the cold plate assembly 22. The heated coolant is transferred to the heat exchanger 26, which may be located remotely from the stack.

Referring to FIG. 2, an example thermoelectric module assembly 20 is shown in more detail. The cold and hot sides 38, 40 are respectively provided by first and second members, such as first and second heat spreaders 46, 48. The insulator plate 50, which is constructed from a plastic, is sandwiched between the first and second heat spreaders 46, 48, constructed from metal, once assembled into a single unit that can be secured to the cold plate assembly 22.

The insulator plate 50 includes apertures 52 within which thermoelectric devices 54 are arranged. In the example, the thermoelectric devices utilize the Peltier effect to provide a cold side adjacent to the first heat spreader 46 and a hot side adjacent to the second heat spreader 48.

Insulator plate 50 includes formed wire channels 60 that receive wires 61 of the thermoelectric devices 54 of the thermoelectric module assembly 20. In the example, three Peltier devices are wired in series with one another.

A matrix of voids 62 is provided in the insulator plate 50 to reduce the thermal mass of the insulator plate 50 and provide air gaps that insulate the first and second heat spreaders 46, 48 from one another. The voids 62 may be any suitable size, shape or pattern. The voids may be deep recesses relative to the thickness of the insulator plate 50 (shown) or extend all the way through the insulator plate 50.

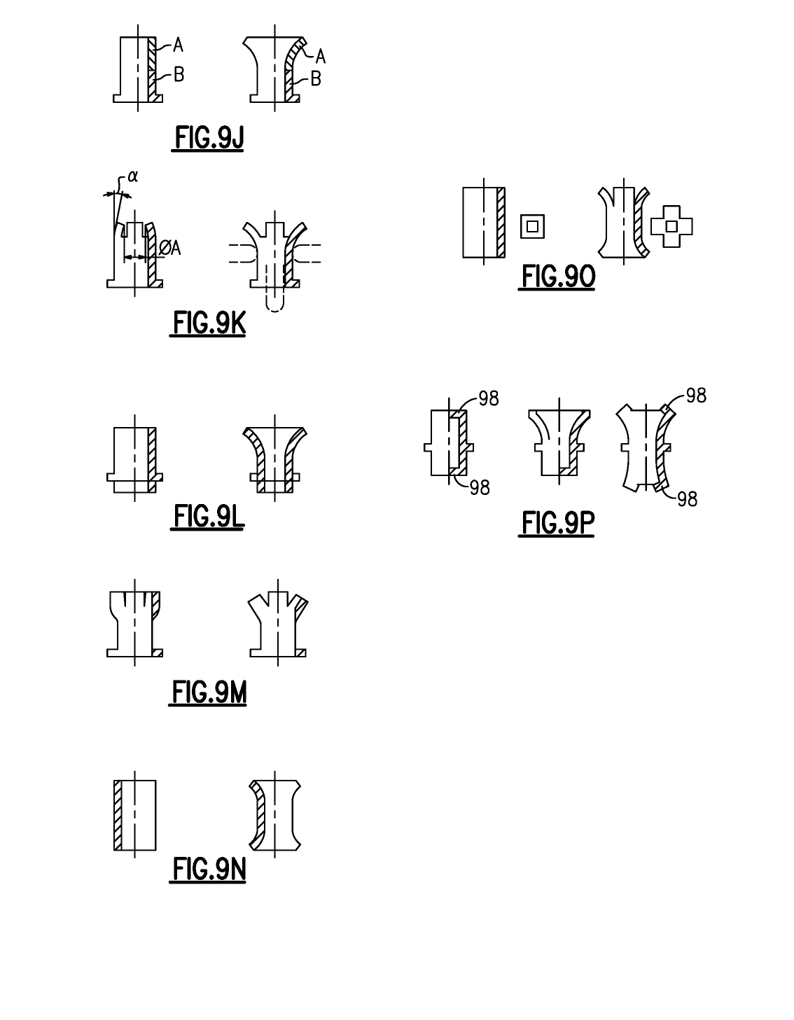

The second heat spreader 48 includes raised pads 64 that extend upward toward the insulator plate 50 to support the thermoelectric devices 54. The second heat spreader 48 can be eliminated and the thermoelectric devices 54 can be mounted directly to the cold plate assembly 22, as shown in FIG. 6 and described below. Returning to FIG. 2, thermal foils 66 may be provided between the thermoelectric devices 54 and the first and second heat spreaders 46, 48 to ensure adequate engagement between the components for thermal efficiency.

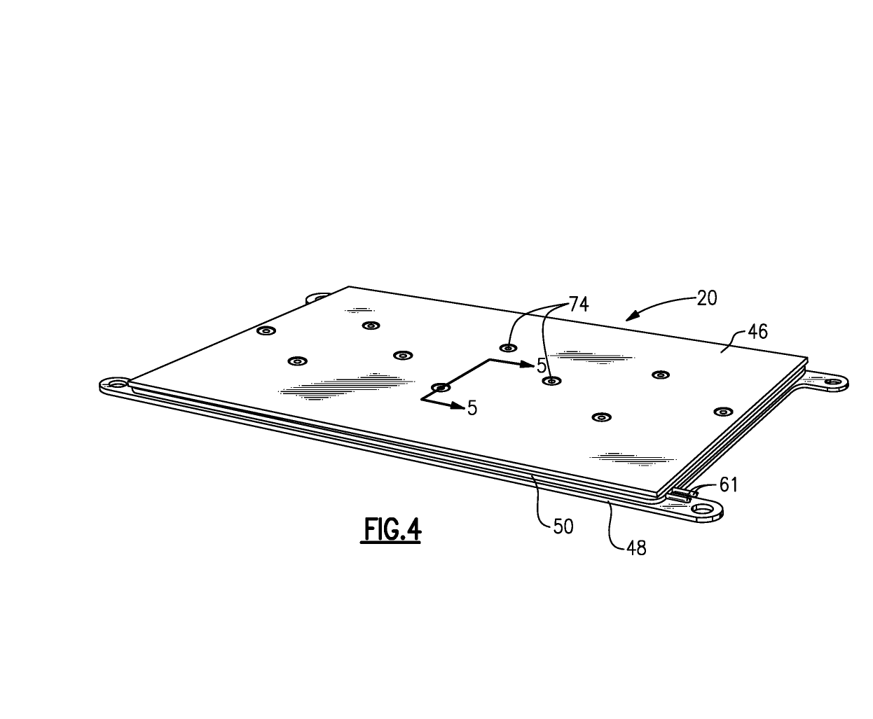

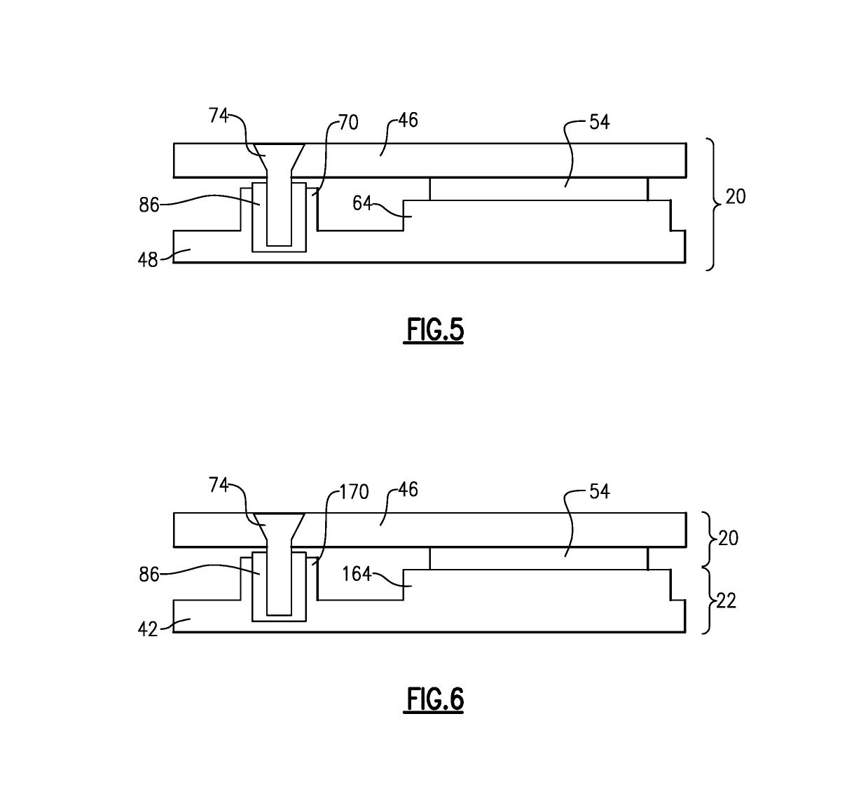

Referring to FIGS. 2 and 3A-3B, the insulator plate 50 includes locators 68, which may be openings. Protrusions 70 may be provided on, for example, the second heat spreader 48 to locate the insulator plate 50 relative to the second heat spreader 48 during assembly. In the example, fasteners 74 extend through holes in the first heat spreader 46 to secure the stack of first and second heat spreaders 46, 48 and the insulator plate 50. The protrusion 70 does not extend to the first heat spreader 46 so that a desired clamp load can be applied to the thermoelectric device 54. The fasteners 74 are tightened to a predetermined torque to provide desired clamp load on the thermoelectric device 54.

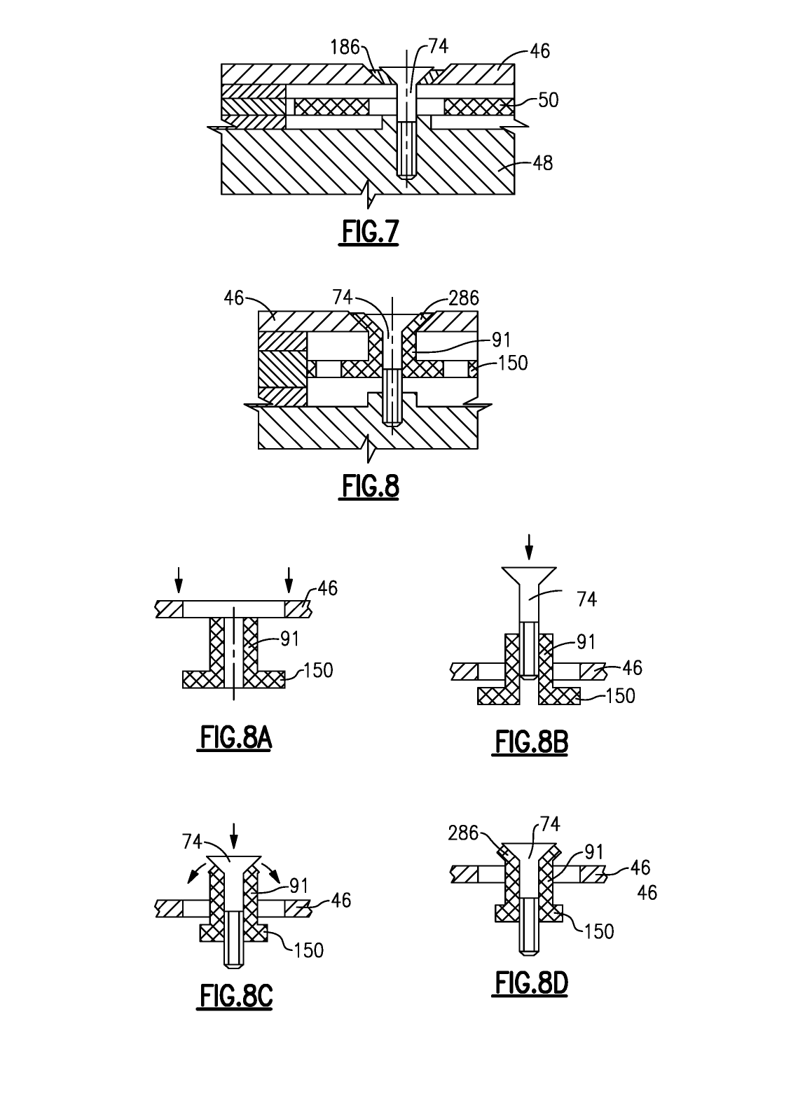

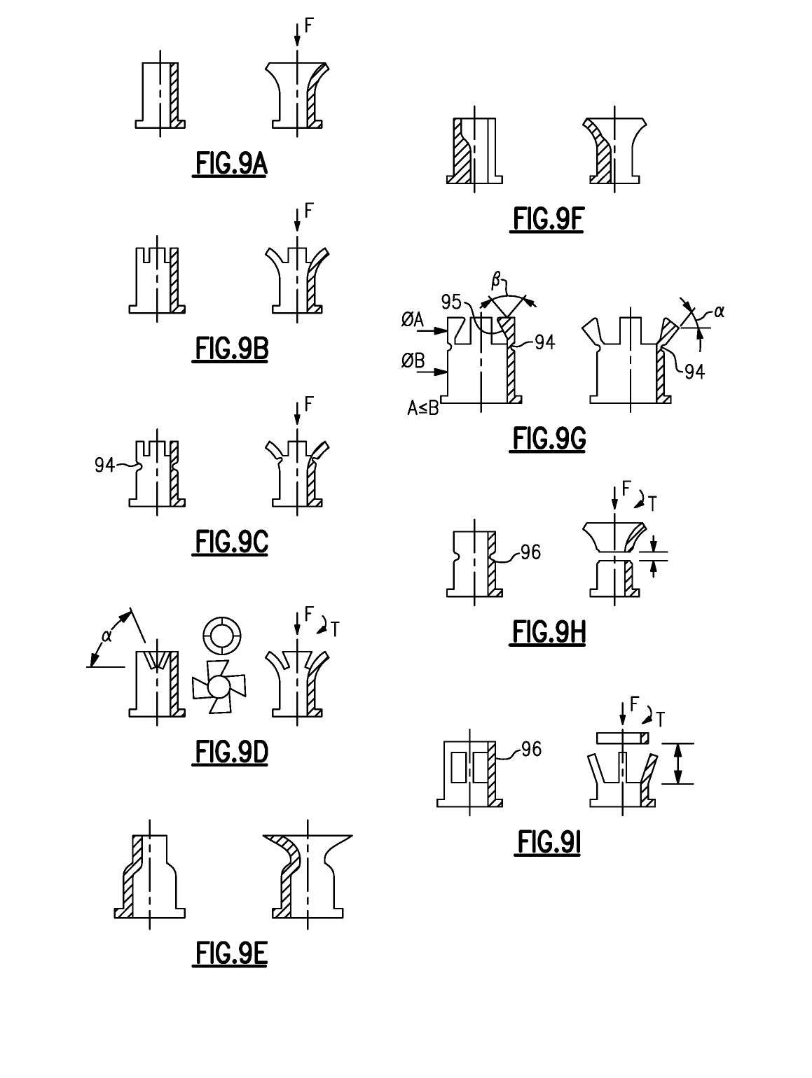

The fasteners 74, which are metallic, can create a thermal short between the first and second heat spreaders 46, 48, which can significantly reduce the thermal efficiency of the thermoelectric module assembly 20. Referring to FIGS. 4 and 5, the thermal insulator 86, constructed from a non-metallic material such as plastic, for example, is arranged in the second heat spreader 48 to thermally isolate the fastener 74 from the second heat spreader 48. Thermal insulator 86 can be pressed or threaded into the protrusion 70. The fastener 74 is threaded into a threaded inner diameter of the thermal insulator 86 to clamp the first and second heat spreaders 46, 48 to one another, although a press-fit fastener can also be used.

As shown in FIG. 6, the second heat spreader 48 can be eliminated and the first heat spreader 46 can be secured to the cold plate assembly 22. In this example, the thermal insulator 86 is installed in the first cold plate 42, which provides the protrusion 170 and the pad 164.

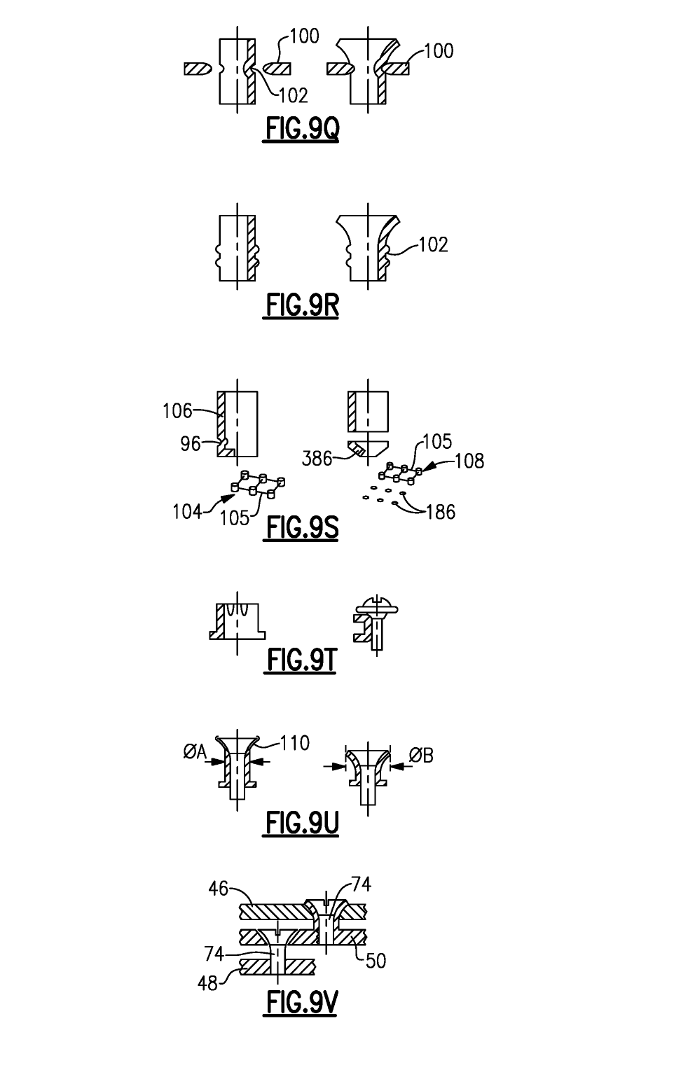

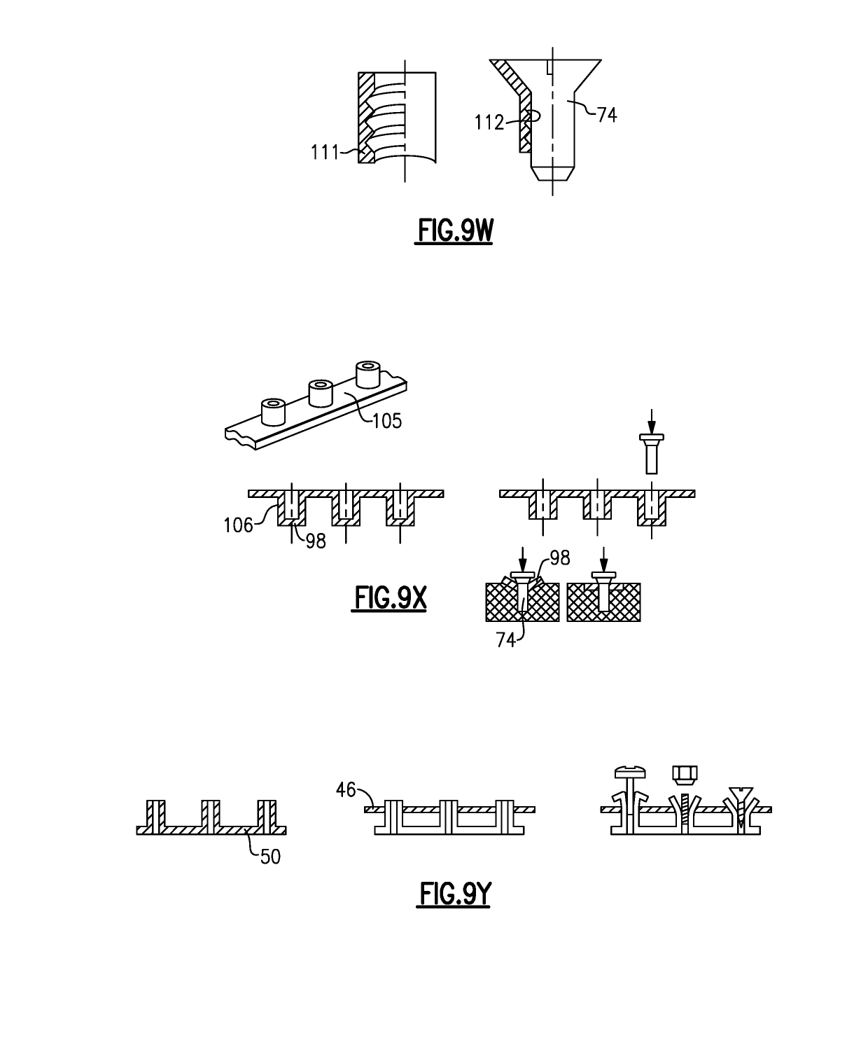

Referring to FIG. 7, the thermal insulator 186, such as a plastic washer, is provided in between the heat spreader 46 and the head of the fastener 74. In the example shown in FIG. 8, the thermal insulator 286 can be integrated into the insulator plate 50 by a neck 91. An end of the thermal insulator neck 91 is deformed by the head of the fastener 74 during assembly, as shown in FIGS. 8A-8D. As the fastener 74 is inserted into the neck 91, its end spreads outward, which forms the washer-like thermal insulator 286. With this embodiment, as compared with the embodiment shown in FIG. 7, a separate washer is not used. Rather, the washer is integrated into the insulator plate 50 to reduce the number of components and simplify assembly.

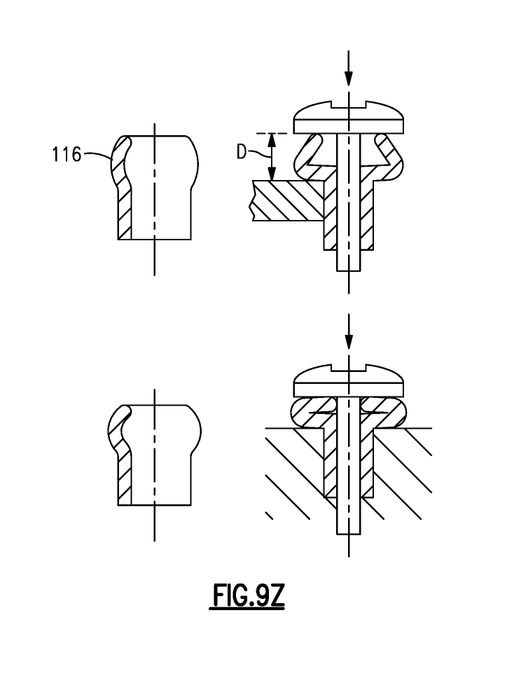

Various example thermal insulator/washer arrangements are depicted in FIGS. 9A-9Z, which generally illustrate similar embodiments to the example illustrated in FIGS. 8-8D and described above. The left side of each Figure illustrates the neck prior to insertion of the fastener and deformation. The right side of each Figure illustrates the neck plastically deformed to provide the integrated thermal insulator/washer. The fastener is omitted for clarity in some illustrations.

In the embodiments shown in FIGS. 9B-9D, slots are provided at the ends of the necks to provide fingers that enable more defined opening of the end as the fastener is inserted, requiring less force. An annular notch 94 is used to define the location at which the washer is formed at the end of the neck. FIG. 9D includes angular slots that better withstand the torque of the screwing process.

FIGS. 9E and 9F respectively provide an interference fit between the neck and the screw at either the top (FIG. 9E) or the bottom (FIG. 9F).

FIG. 9G depicts a crown configuration with the notch 94. An inwardly facing ramp has an angle β and is provided at an inner diameter of the end. When opened the end is provided at an angle α. The angle α defines the chamfer or taper, and angle β defines the opening properties of the thermal insulator as the fastener forces the end radially outwardly.

FIGS. 9H and 9I illustrate an arrangement in which the neck has an annular groove 96 that creates a frangible connection. Torque from the fastener head applied to the inner diameter of the neck during assembly will shear the end from the neck at the annular groove 96.

Multiple materials are used in the embodiment shown in FIG. 9J. In one example, material A is overmolded onto material B. Material B may be more easily plastically deformed that material A, for example. The materials A and B may also be 3D printed, if desired.

In the example shown in FIG. 9K, the end is tapered inward at an angle α to provide an inner diameter A that is sized to capture the fastener prior to final assembly. As the fastener is threaded into the heat spreader or cold plate, the end opens up.

The thermal insulator in FIG. 9M has a cross-sectional wall thickness that varies substantially from the neck to the end. The end provides the thermally insulative function with the heat spreader, and thus, thicker plastic is more desirable for this portion. A thinner neck saves material, and thus, cost and weight. In FIG. 9N, the top and bottom of the neck may be plastically deformed during insertion of the fastener into the thermal insulator.

Generally cylindrical or frustoconical shapes have been shown in FIGS. 8-9N. It should be understood, however that other shapes can be used, for example, polygonal, such as a square (FIG. 9O).

It may be desirable to control the ingress of debris into the interior of the thermoelectric module assembly during assembly. A wall 98 can be used at one or both ends of the neck to provide a seal. The wall 98 is pierced by the fastener during assembly.

In the examples shown in FIGS. 9Q and 9R, the neck can be clipped by a tool 100 to form recesses 102 that can be used as a point of articulation for the end, frangible connections or locating features used in assembly.

Multiple thermal insulators 386 are connected to a bottom end of a structure 106 by a frangible connection 96 to provide a sub-assembly 104, as shown in FIG. 9S. Sprues 105 interconnect the structures 106 into a frame and provide a spacing that corresponds to the spacing of the fasteners 74 (see FIG. 2) securing the thermoelectric module assembly together when assembled. During assembly, a fastener 74 is received in each structure 106, and the fasteners are threaded into the heat spreader or cold plate, which shears the thermal insulators 386 from their respective structures 106. The remainder 108 of the sub-assembly 104 can then be discarded.

FIG. 9T illustrates that a non-conical fastener head can be used to deform the end of the neck. A thin clip 110 can be used to retain the fastener to the neck prior to assembly, as shown in FIG. 9U. The end of the neck expands from a diameter A to a diameter B upon tightening of the fastener, as explained in connection the embodiments described above.

A two-tiered fastening arrangement can be used, as illustrated in FIG. 9V. A first fastener 74 secures the insulator plate 50 to the second heat spreader 48, and a second fastener 74 secures the first head spreader 46 to the insulator plate 50. This arrangement may provide improved thermal insulation.

A metal coil insert 112 may be provided between the fastener 74 and the neck 111, as shown in FIG. 9W. In this manner, the relatively weak plastic threads of the neck will not be damaged by the metallic fastener 74 during assembly.

FIG. 9X illustrates an arrangement similar to that of FIGS. 9P and 9S. The structures 106 are joined to one another at a desired spacing in a roll. A bottom wall 98 is provided, which is pierced by the fastener during assembly. The wall 98 is detached by the fastener 74 as it is tightened, and the remainder of the structures 106 and roll is discarded.

FIG. 9Y is similar to FIG. 9X in that the necks are joined in a roll. Any number of fastener types can be used to secure the first heat spreader 46 to the insulator plate 50 and deform the ends, as described in the embodiments above.

A bulbous end 116 is provided that is shaped to encourage buckling of the end as the fastener 74 is tightened from a distance D that is more than twice the wall thickness of the end. As a result, the thickness of the insulation beneath the fastener head is effectively doubled when the assembled, however, the initial diameter of the end is relatively small.

It should be understood that the arrangements shown in FIGS. 8A-9Z can be used for fastening and/or thermally, electrically, or mechanically insulating printed circuit board or other non-thermoelectric devices. These arrangements create an insulating layer on joint connections (e.g. screw, bolt, rivet) that form during assembly. Several washers, spacers or screw/bolt/rivet head insulations can be integrated in a single part/frame and assembly step. The disclosed designs allows self-centering of screws/bolts/rivets without a cone-shaped head on the insulator.

In operation, an undesired battery temperature is detected by the controller 34. The thermoelectric devices 50 are powered to produce a cold side of the thermoelectric device 54 that is transferred to the first heat spreader 46 adjacent to the battery 14 increasing the temperature differential between these components and increasing the heat transfer therebetween. Heat from the battery is transferred from the first heat spreader 46 through the thermoelectric device 54 to the second heat spreader 48. However, the isolator plate 50 acts to prevent heat from being transmitted from the first heat spreader 46 to the second heat spreader 48. The thermal insulators 86 further prevent undesired heat transfer between the first and second heat spreaders. The second heat spreader 48 rejects heat to the coolant within the cold plate assembly 22. Coolant is circulated from the cold plate assembly 22 to the heat exchanger 26, which rejects heat to the ambient environment, and this heat transfer rate may be increased by use of the blower 28.

It should be understood that although a particular component arrangement is disclosed in the illustrated embodiment, other arrangements will benefit herefrom. Although particular step sequences are shown, described, and claimed, it also should be understood that steps may be performed in any order, separated or combined unless otherwise indicated and will still benefit from the present invention.

Although the different examples have specific components shown in the illustrations, embodiments of this invention are not limited to those particular combinations. It is possible to use some of the components or features from one of the examples in combination with features or components from another one of the examples.

Although an example embodiment has been disclosed, a worker of ordinary skill in this art would recognize that certain modifications would come within the scope of the claims. For that reason, the following claims should be studied to determine their true scope and content.

What is claimed is:

1. A thermoelectric module assembly for thermally conditioning a component, the assembly comprising:
first and second members are spaced apart from one another and are configured to respectively provide cold and hot sides;
an insulator plate is arranged between the first and second members;
a thermoelectric device is arranged within the insulator plate and is operatively engaged with the first and second members;
a fastening element secures the first and second members to one another about the insulator plate in an assembled condition; and
a thermal insulator is provided in one of the first and second members and is configured to receive the fastening element.

2. The assembly according to claim 1, wherein the first and second members are metallic and the insulator plate is a plastic.

3. The assembly according to claim 1, wherein the fastening element is metallic and the thermal insulator is non-metallic.

4. The assembly according to claim 1, wherein the second heat member includes a raised pad supporting the thermoelectric device.

5. The assembly according to claim 4, comprising a thermal foil arranged between and in engagement with the pad and the thermoelectric device.

6. The assembly according to claim 4, wherein the thermoelectric device is a Peltier device.

7. The assembly according to claim 1, wherein the insulator plate includes an opening and the second member includes a protrusion that cooperates with the opening to laterally locate the insulator plate and the second member relative to one another.

8. The assembly according to claim 7, wherein the fastening element is a threaded fastener secured to a threaded inner diameter of the protrusion.

9. The assembly according to claim 7, wherein the insulator plate has at least four discrete protrusions that surround the thermoelectric device.

10. The assembly according to claim 1, wherein the first and second members are first and second heat spreaders, the first and second heat spreaders and the insulator plate secured to one another to provide the thermoelectric module assembly.

11. The assembly according to claim 1, wherein the first member provides a heat spreader and the second member provides a cold plate assembly, the cold plate assembly includes cooling passages configured to receive a coolant circulated through the cooling passages.

12. The assembly according to claim 1, wherein the thermal insulator is press-fit into the second member.

13. The assembly according to claim 1, wherein the thermal insulator is threaded into the second member.

14. The assembly according to claim 1, wherein the fastening element is threaded into the thermal insulator.

15. The assembly according to claim 1, wherein the fastening element is press-fit into the thermal insulator.

16. The assembly according to claim 1, wherein an interface between the fastening element and the thermal insulator provides a clamping load on the thermoelectric device.

17. The assembly according to claim 1, wherein the fastening element is thermally isolated from the second member by the thermal isolator.

18. The assembly according to claim 1, wherein the thermal insulator is a washer engaging the first member.

19. The assembly according to claim 18, wherein the thermal insulator is integrated with the insulator plate.

20. An insulating assembly comprising:
an insulator plate that includes a neck with an end;
a component with a hole aligned with the end; and
a fastener is received in the hole and is secured to the neck, the fastener is configured to plastically deform the end into engagement with the component during assembly and isolate the component from the fastener.
